(19) United States
(12) Patent Application Publication
(10) Pub. No.: US 2008/0202580 A1
(43) Pub. Date: Aug. 28, 2008

(54) Light power cell system

(76) Inventor: Gary Paul Bohannon, Chewelah, WA (US)

Correspondence Address: Gary P. Bohannon, PO Box 575, Chewelah, WA, 99109-0575, US

(21) Appl. No.: 11/893,031

(22) Filed: Jan. 17, 2008

Related U.S. Application Data
(60) Provisional application No. 60/837,214, filed on Aug. 14, 2006.

(51) Int. Cl. H01L 31/04

(52) U.S. Cl. 136/252

(57) ABSTRACT

A system and method is directed to capturing light energy from an artificial light source. The method includes arrangement of systematic placement of capturing devices in a systematic way associated with one or more user artificial light producing devices and transmitting the captured electrical energy to various separate devices to be used in a manner that is allowable for electrical energy being produced by a collector and distribution unit of said energy captured by the arranged devices.

### CLAIM OF PRIORITY

This application claims priority to U.S. Provisional Patent Application Ser. No. 60/837,214 filed 14 Aug. 2006 entitled “Light power cell system,” which is hereby incorporated by reference herein in its entirety.

### BACKGROUND

Artificial light producing devices have been in our life and usage the world over for many years and are a part of our lives everyday and the large numbers are growing with the dependency of these artificial light producing units. These light producers allow us to see at night or in dark buildings and are being utilized constantly everywhere we live and work and commute to and from our homes and work areas. They allow us to work uninterrupted without regard to the normal Sun producing element which our world revolves around. These artificial light producers are expensive to operate yet necessary.

Collecting energy from these artificial light producers work also with the growing of the food we consume. With the dependency of this light source it also provides us with an unlimited amount of electrical energy that goes unused and un attended in these current circumstances and can be made useful to the way we currently use our electricity produced by but not limited to Nuclear, water, wind and solar.

unfortunately, existing electrical management systems do not address many issues relating to reusing the spent artificially produced energy. The present invention advances the state of the art in the areas of accessing this spent energy produced by artificial light and dispersing it to the needs of the users and saving of huge amounts of consumer dollars.

### SUMMARY

According to an embodiment of the present invention, a systematic capturing of the spent artificial light energy and converting it to electricity can be accomplished and the amount captured is dependent on the number of end unit capturing devices placed in a system. These systems can work independently or on a broader scale to business, Hospitals and State and local offices. By systematically capturing and converting artificial light energy into electricity, it is used in the system producing the light originally in the form of a storage device or utilizing the captured electrical energy other than locally.

The foregoing, and other features and advantages of the invention, will become further apparent from the following detailed description of the presently preferred embodiments, read in conjunction with the accompanying drawings.

### DESCRIPTION OF THE DRAWINGS

FIG. 100 is a flow diagram of a Light power cells system, illustrating an exemplary operating environment for embodiment of the invention;

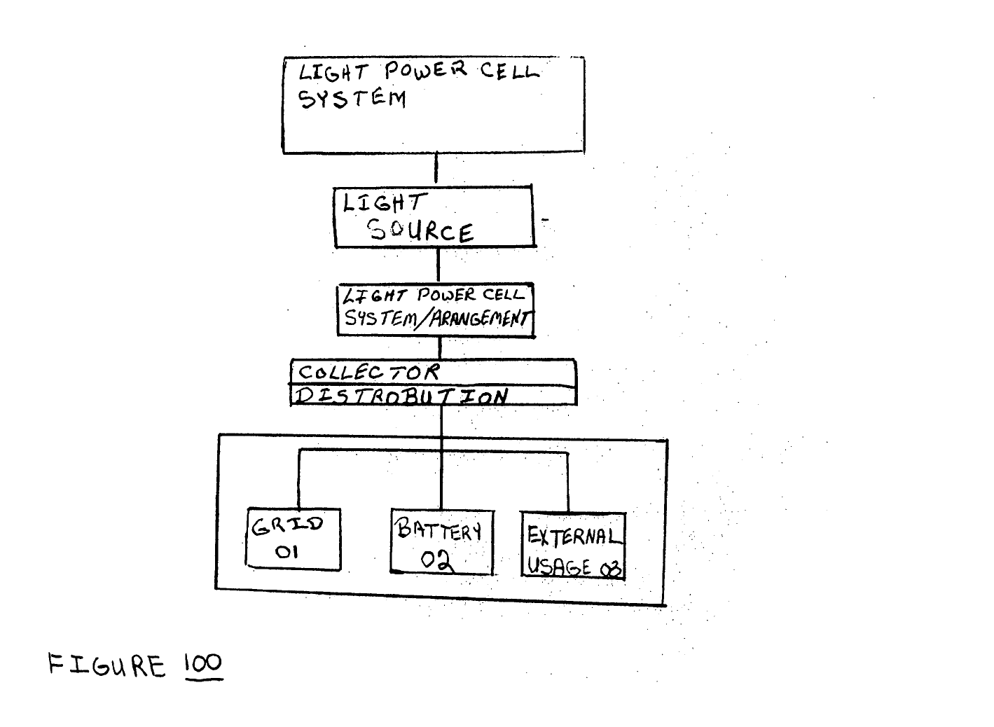

FIG. 200 is a flow diagram of a Light Power Cell System, illustrating detailed embodiment of the invention starting with any type artificial light source, FIG. 210; Systematic arrangement of light capturing devices, FIG. 220; and receipt of the collector distribution unit, FIG. 230; and

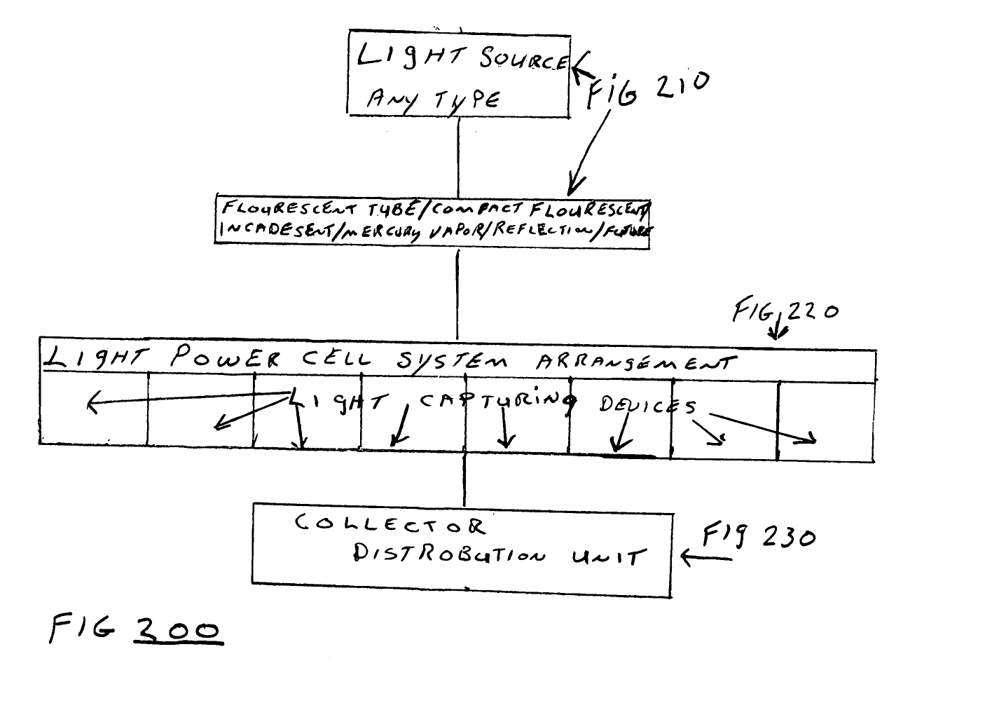

FIG. 300 is a flow diagram view of an illustrative collector distribution unit, FIG. 310 and how the captured electrical direct current can be handled, Grid, FIG. 320; Battery, FIG. 330; and Externally, FIG. 340, with an embodiment of the invention; and

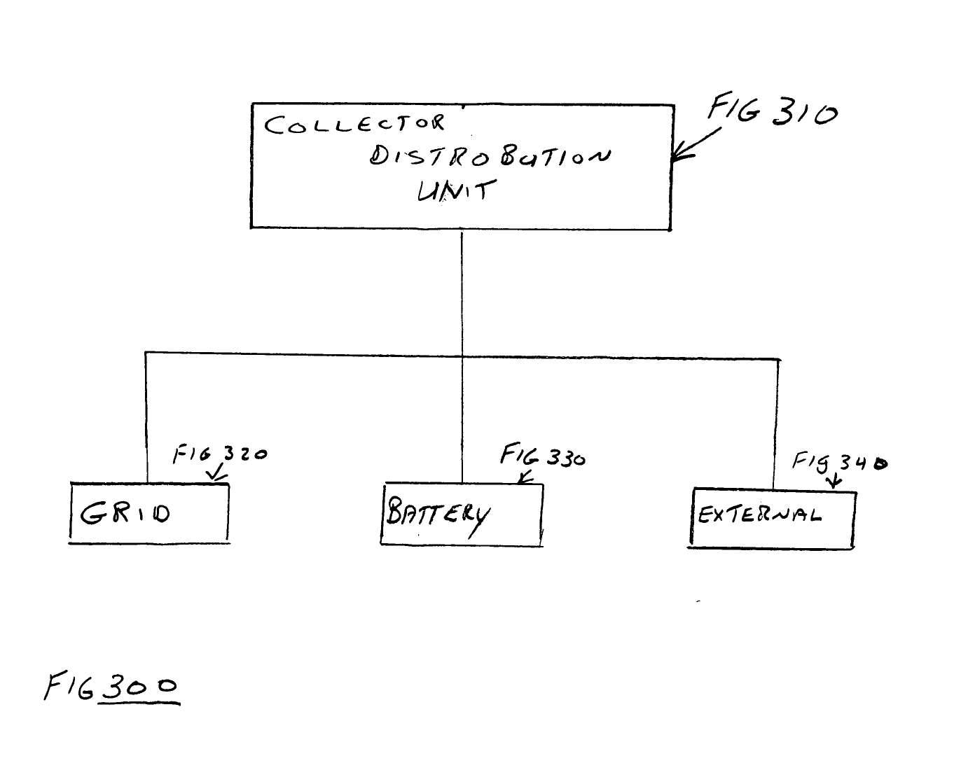

FIG. 400 is an example of an artificial light assembly source; of which is a florescent tube, FIG. 410, type fixture and Alternating Circuit wires, FIG. 401; showing the systematic arrangement of the light capturing device collectors, FIG. 420 behind and to the sides of the tube assemblies, FIG. 410; with the external leads of Direct Current, FIG. 430; in accordance with an embodiment of the invention;

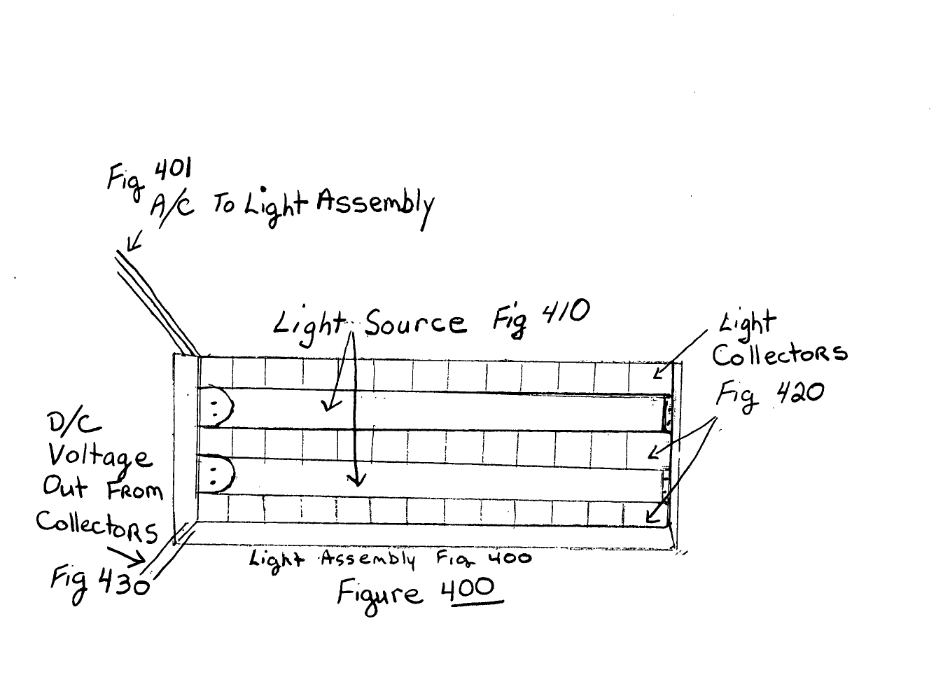

FIG. 500 is an example of yet another artificial light source assembly, FIG. 501; of which is a florescent tube type, FIG. 510, fixture showing the systematic arrangement of the capturing collectors devices, FIG. 530 behind and also to the sides of the tube assemblies and to the immediate back sides as in the previous example with the external leads of Direct Current, FIG. 520; in accordance with an embodiment of the invention; and

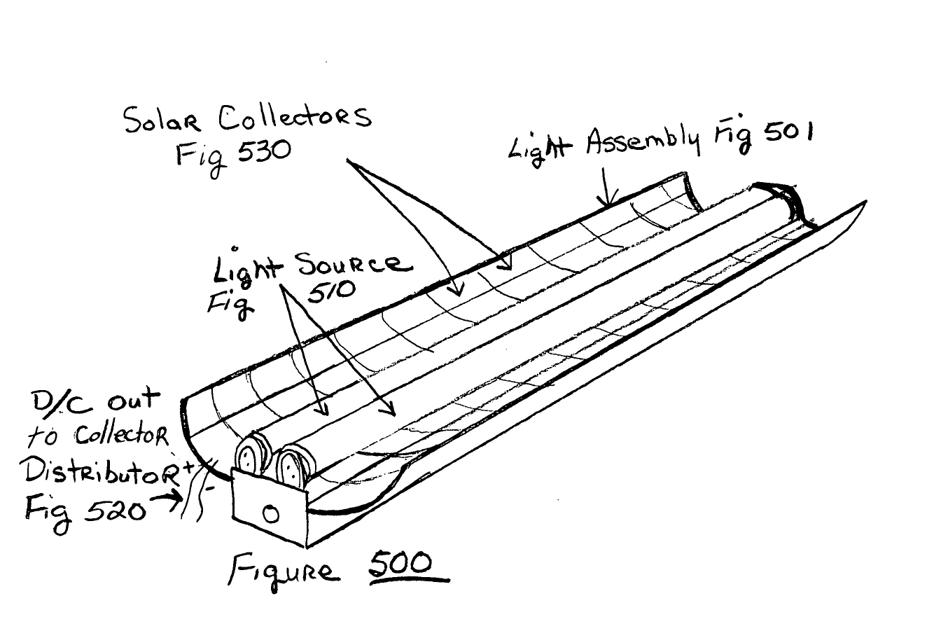

FIG. 600 is an example of yet another artificial light assemble, FIG. 601, source and Alternating Current leads, FIG. 610, of which is not limited to an example of Halogen or Mercury Vapor type artificial light bulb, FIG. 640, fixture showing the systematic arrangement of the capturing collectors devices above the artificial light source, FIG. 640 encircling the fixture sides of the previous examples, FIG. 400, FIG. 500 with the external leads of Direct Current, FIG. 620 in accordance with an embodiment of the invention; and

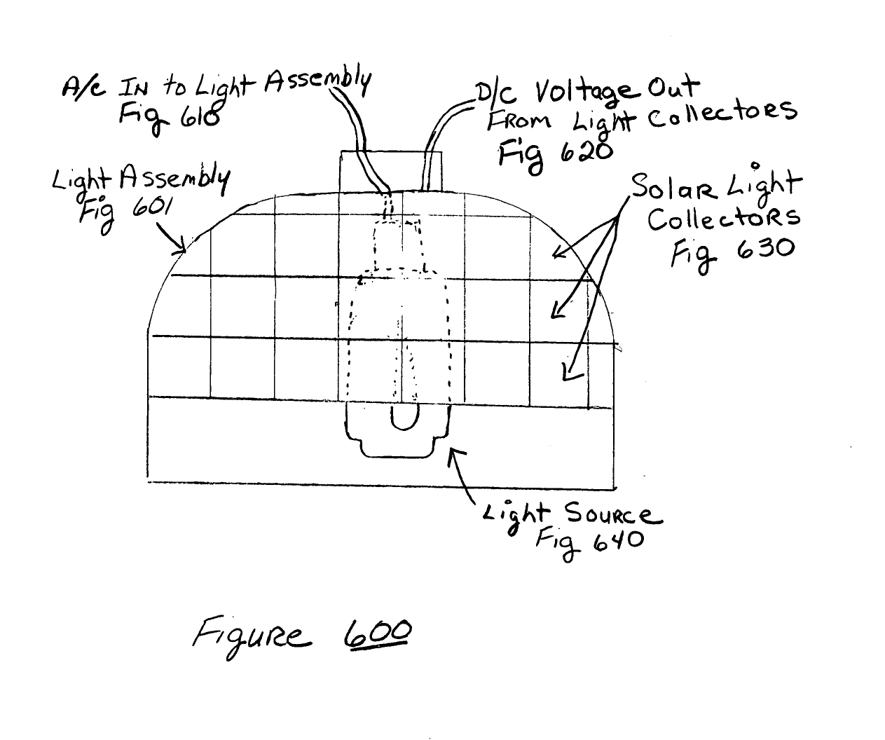

### DETAILED DESCRIPTION

the invention described herein provides methods and apparatus for capturing the artificial light energy produced by the artificial light. Although the invention can take a number of different forms, in one example a artificial light producing assembly can pass the energy transferred in the form of Direct Current to the collector distribution unit whereas it will then pass the energy on to the grid of electrical formation, store the energy in the form of batteries of energy holding devices or be transferred to another end unit requiring the energy be in the form of Direct Current or in the form of Alternating current. With the invention includes a system of artificial light producing end units which can be added to or reduced in numbers at any time and controlled by the collector distribution units. Each local collector distribution units can, in turn, be placed in selective control of one or more artificial light producing sources and devices.

once all artificial light sources are no longer producing the artificial light then the collector distribution of the Direct current will cease and the collector distribution unit will not allow any form of energy to reenter the capturing devices on the artificial light sources.

other features can be incorporated into the systematic system described above. For example, artificial lights that are regulated by timers or motion detecting devices can come on and the energy produced by them is automatically collected and distributed with no other input from the user. Once the unit has returned to an off state then the flow of electricity from that individual or set of light producing units is stopped. On again then the automatic systematic collection and distribution resumes.

added to the features described in [0014] is the capability to add at anytime other artificial light producing units with the incorporated systematic energy capturing system; Light Power Cell System and further enhance the potential of the overall output of electricity.

It is anticipated that the invention will be embodied in other specific forms, not specifically described, that do not depart from its spirit or essential characteristics. The described embodiments are to be considered in all respects only as illustrative and not restrictive, the scope of the invention being defined by the appended claims and equivalents thereof.

I claim:

1. A systematic arrangement of energy capturing devices so placed to pass the captured electrical energy to a controller distribution unit comprising: artificial light or lights producing light energy and through the usage of light capturing device so arranged in a systematic way to capture the electrical energy produced by the artificial light producers devices and allowing the energy to pass to the collector and distributor.

2. The systematic arrangement of energy capturing devices can be either local to the collector distributor unit or be transferred to the unit in any matter appropriate to electrical energy conducting components'.
